(19) United States
(12) Patent Application Publication
(10) Pub. No.: US 2010/0155813 A1
(43) Pub. Date: Jun. 24, 2010

(54) SEMICONDUCTOR MEMORY DEVICE HAVING STACK GATE STRUCTURE AND METHOD FOR MANUFACTURING THE SAME

(76) Inventors: Takeshi MURATA, Kawasaki-shi (JP); Hiroyuki NITTA, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/646,009

(22) Filed: Dec. 23, 2009

(30) Foreign Application Priority Data
Dec. 24, 2008 (JP) 2008-328069

(51) Int. Cl. H01L 27/115; H01L 21/8247

(52) U.S. Cl. 257/316; 438/258; 257/E21.681; 257/E27.103

(57) ABSTRACT

A semiconductor memory device includes select transistors, cell transistors, and cell units. The select transistors formed on a substrate and include first electrodes. The cell transistors include second electrodes with a charge storage layer and a control. The cell units including a plurality of the cell transistors connected together in series between the two select transistors. A distance between the first electrodes and a distance between the first electrodes which is adjacent to the second electrodes and adjacent second electrodes are each at least double a distance between second electrodes. A surface of the substrate between second electrodes is flush with the surface of the substrate between the first electrode and the adjacent second electrodes. The surface of the substrate between the first electrodes is positioned lower than the surface of the substrate between the first electrodes and the second electrodes.

### CROSS-REFERENCE TO RELATED APPLICATIONS

This application is based upon and claims the benefit of priority from prior Japanese Patent Application No. 2008-328069, filed Dec. 24, 2008, the entire contents of which are incorporated herein by reference.

### BACKGROUND OF THE INVENTION

1. Field of the Invention

The present invention relates to a semiconductor memory device and a method for manufacturing the semiconductor memory device. The present invention relates to, for example, the configuration of a semiconductor memory having a stack gate structure.

2. Description of the Related Art

EEPROMs (Electrically Erasable and Programmable Read Only Memories) are conventionally known as nonvolatile semiconductor memories. In particular, NAND flash memories are known as EEPROMs that can be highly integrated.

Jpn. Pat. Appln. KOKAI Publication No. 2004-6449 describes a NAND flash memory including memory cell transistors each having a stack gate with a charge storage layer and a control gate, and select transistors. Side wall spacers are generally formed on a side wall of each stack gate, a side wall of a gate electrode of each select transistor, and a side wall of a gate electrode of each MOS transistor in a peripheral circuit.

In this case, the region between the stack gates is completely filled with an insulating film serving as a side wall spacer. Thus, when the insulating film is etched to form a side wall spacer, portions of a semiconductor substrate located between the stack gates are not etched.

However, in regions other than those between the stack gates, the surface of the semiconductor substrate is etched during the etching process. This may degrade the operational reliability of the NAND flash memory.

### BRIEF SUMMARY OF THE INVENTION

A semiconductor memory device according to an aspect of the invention includes,

select transistors formed on a semiconductor substrate and including first gate electrodes;

memory cell transistors including second gate electrodes with a charge storage layer and a control gate; and

a plurality of a memory cell units including a plurality of the memory cell transistors connected together in series between the two select transistors,

a distance between the first gate electrodes in a one of the plurality of the memory cell units and the first gate electrodes in an other of the plurality of the memory cell units, and a distance between one of the first gate electrodes and one of the second gate electrodes adjacent to each other, being each at least double a distance between the adjacent second gate electrodes,

a surface of the semiconductor substrate between the adjacent second gate electrodes being flush with the surface of the semiconductor substrate between one of the first gate electrodes and one of the second gate electrodes adjacent to each other, and

the surface of the semiconductor substrate between the first gate electrodes in the one of the plurality of the memory cell units and the first gate electrodes in the other of the plurality of the memory cell units being positioned lower than the surface of the semiconductor substrate between one of the first gate electrodes which is adjacent to the second gate electrodes and an adjacent one of the second gate electrodes.

A method for manufacturing semiconductor memory device according to an aspect of the invention includes,

forming select transistors including first gate electrodes formed on a first region of a semiconductor substrate with a first insulating film interposed therebetween and first impurity diffusion layers functioning as a source or a drain;

forming a plurality of memory cell transistors including second gate electrodes having a charge storage layer and a control gate sequentially formed on a second region of the semiconductor substrate with a second insulating film interposed therebetween, and second impurity diffusion layers functioning as a source or a drain, any of the second impurity diffusion layers being connected to one of the first impurity diffusion layers, a distance between the adjacent first gate electrodes and a distance between the first gate electrodes which is adjacent to the second electrodes and the adjacent one of the second gate electrodes being each at least double a distance between the adjacent second gate electrodes;

forming a third insulating film so that the third insulating film covers the first gate electrodes, the second gate electrodes, and a surface of the semiconductor substrate; and

removing the third insulating film from the surface of the semiconductor substrate in a region between the adjacent first gate electrodes, with the third insulating film left on a surface of one of the first gate electrodes which is adjacent to the second gate electrodes and on a surface of the second gate electrodes.

### BRIEF DESCRIPTION OF THE SEVERAL VIEWS OF THE DRAWING

FIG. 1 is a block diagram of a flash memory according to a first embodiment of the present invention;

FIG. 2 is a plan view of a memory cell array according to the first embodiment;

FIG. 3 is a sectional view taken along line 3-3′ in FIG. 2;

FIG. 4 is an enlarged view of FIG. 3;

FIG. 5 to FIG. 16 are sectional views of the first step to twelfth step of manufacturing a memory cell array according to the first embodiment;

FIG. 17 is a sectional view of a memory cell array;

FIG. 18 is a sectional view of a shunt region in the memory array according to the first embodiment;

FIG. 19 is a sectional view of a memory cell array according to a variation of the first embodiment;

FIG. 20 is a sectional view of peripheral transistors according to a second embodiment of the present invention; and

FIG. 21 to FIG. 25 are sectional views of the first step to fifth step of manufacturing peripheral transistors according to the second embodiment.

### DETAILED DESCRIPTION OF THE INVENTION

Embodiments of the present invention will be described below with reference to the drawings. In the description, the same components are denoted by the same reference numerals throughout the drawings. Furthermore, the drawings are schematic, and it should be noted that the relationships between thicknesses and planar dimensions, the ratio of thicknesses of layers, and the like are different from actual ones.

### First Embodiment

A semiconductor memory device according to a first embodiment of the present invention and a method for manufacturing the semiconductor memory device will be described below taking a NAND flash memory as an example.

### <General Configuration of the NAND Flash Memory>

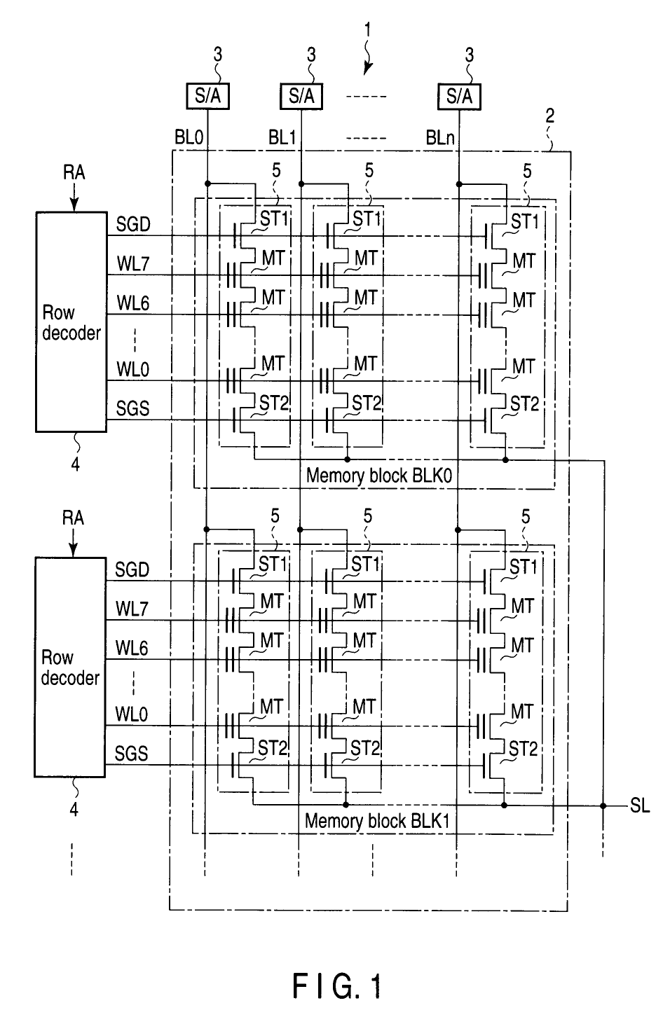

First, the general configuration of a NAND flash memory according to the present embodiment will be described with reference to FIG. 1. FIG. 1 is a block diagram showing a part of the configuration of the NAND flash memory according to the present embodiment.

As shown in FIG. 1, a NAND flash memory 1 includes a memory cell array 2, sense amplifiers 3, and row decoders 4. First, the configuration of the memory cell array 2 will be described.

The memory cell array 2 includes a plurality of memory blocks BLK0 to BLKm (m is a natural number equal to or larger than two). In the description below, when not distinguished from one another, the memory blocks BLK0 to BLKm are simply referred to as memory blocks BLK. Each memory block BLK includes (n+1) (n is a natural number equal to or larger than one) memory cell units 5.

Each of the memory cell units 5 includes, for example, eight memory cell transistors MT and select transistors ST1 and ST2. Each of the memory cell transistors MT includes a stack gate structure having a charge storage layer (for example, a floating gate) formed on a semiconductor substrate with a gate insulating film interposed therebetween, and a control gate formed on the charge storage layer with an inter-gate insulating layer interposed therebetween. The number of memory cell transistors MT is not limited to 8 but may be 16, 32, 64, 128, 256, or the like; no limitation is placed on the number of memory cell transistors MT. The adjacent memory cell transistors share a source and a drain. The memory cell transistors are arranged between the select transistors ST1 and ST2 so that current paths in the memory cell transistors MT are connected together in series. A drain of one of the series connected memory cell transistors MT which is located at one end of the arrangement of the memory cell transistors MT is connected to a source of the select transistor ST1. A source of one of the series connected memory cell transistors MT which is located at the other end of the arrangement of the memory cell transistors MT is connected to a drain of the select transistor ST2.

A conductive film (floating gate), for example, silicon, may be used as the charge storage layer in the memory cell transistor. Alternatively, the charge storage layer may be an insulating film (MONOS structure). In this case, the stack gate includes a charge storage layer formed on a gate insulating film using an insulating film, a block layer formed on the charge storage layer using a material having a higher dielectric constant than the charge storage layer, and a control gate formed on the block layer.

Like the memory cell transistor MT, each of the select transistors ST1 and ST2 has a stack gate structure. However, in the select transistors ST1 and ST2, the inter-gate insulating film is removed from some regions to electrically connect a lower gate and an upper gate of the stack gate structure together.

In each of the memory blocks BLK, control gates of the memory cell transistors MT on the same row are all connected to one of word lines WL0 to WL7. Gates of the select transistors ST1 for memory cells on the same row are all connected to a select gate line SGD. Gates of the select transistors ST2 for memory cells on the same row are all connected to a select gate line SGS. For simplification of description, the word lines WL0 to WL7 are hereinafter simply referred to as word lines WL. Sources of the select transistors ST2 are all connected to a source line SL. Both the select transistors ST1 and ST2 are not required. One of the select transistors ST1 and ST2 may be omitted if the provided select transistor allows the memory cell unit to be selected.

In the memory cell array 2 configured as described above, drains of the select transistors ST1 in the memory cell units 5 on the same column are all connected to one of bit lines BL0 to BLn. The bit lines BL0 to BLn are sometimes simply called the bit lines BL. That is, the bit lines BL connect the memory units 5 in a plurality of memory blocks BLK together. On the other hand, the word lines WL and the select gate lines SGD and SGS connect the memory units 5 together in the same memory block BLK. Furthermore, the memory cell units 5 included in the memory cell array 2 are all connected to the same source line SL.

Additionally, data is written to a plurality of the memory cell transistors MT connected to the word line WL, at a time. This unit is called a page. Moreover, data is deleted from the memory cell units 5 in the same memory block BLK at a time. That is, the memory block BLK corresponds to an erase unit.

To read data, the sense amplifier 3 senses and amplifies data read from the memory cell transistor MT to the bit line BL. In this case, the sense amplifier 3 senses a current flowing through the bit line BL or the voltage on the bit line. Furthermore, to write data, the sense amplifier 3 transfers the data to the bit lines BL to write the data to all the bit lines at a time.

The row decoder 4 is provided for each of the memory blocks BLK. For a data write operation, a data read operation, and data erasure, the row decoder 4 applies voltages to the select gate lines SGD and SGS and word lines WL connected to the corresponding memory block BLK based on externally provided row addresses RA.

### <Details of the Configuration of the Memory Cell Array 2>

Now, the details of the configuration of the memory cell array 2 will be described.

### <Planar Configuration>

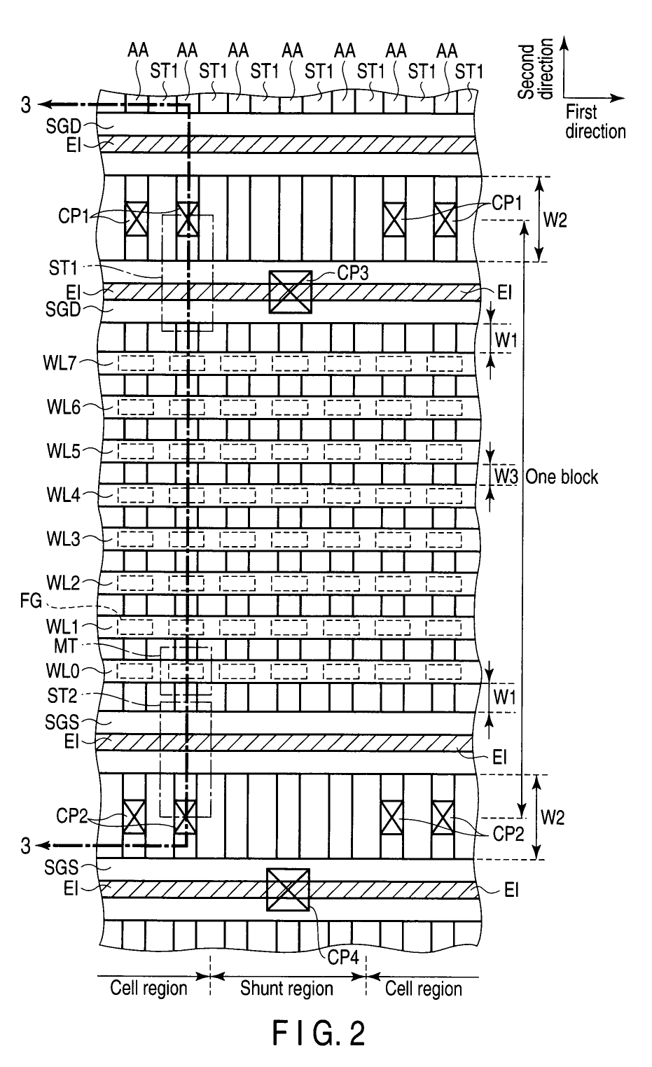

First, the planar configuration of each memory block BLK will be described with reference to FIG. 2. FIG. 2 is a plan view of the memory block BLK.

As shown in FIG. 2, the memory cell array 2 includes cell regions in each of which the memory cell unit 5 holding data is formed and shunt regions in each of which gates of the select transistors ST1 and ST2 are connected to a shunt wire. The cell regions and the shunt regions are alternately arranged along a first direction in a semiconductor substrate surface.

A plurality of strips of element regions AA are provided in a semiconductor substrate 10 in the cell and shunt regions along a second direction orthogonal to the first direction. An isolation region STI is formed between the adjacent element regions AA. The isolation region STI electrically separates the element regions AA from each other.

The strips of word lines WL and select gate lines SGD and SGS extending in the first direction are formed so as to stride over a plurality of the element regions AA in the cell and shunt regions. In each of the cell regions, the charge storage layer (floating gate FG) is provided in a region in which the word line WL crosses the element region AA. The memory cell transistor MT is provided in a region in which the word line WL crosses the element region AA. The select transistor ST1 is provided in a region in which the select gate line SGD crosses the element region AA. The select transistor ST2 is provided in a region in which the select gate line SGS crosses the element region AA. An impurity diffusion layer serving as a source region or a drain region of each of the memory cell transistor MT and select transistors ST1 and ST2 is formed in the element region AA between the word lines WL, between the select gate lines, and between the word line and the select gate line, which are adjacent to each other in the first direction. An arrangement similar to that in the cell region is also provided in the shunt region. However, the arrangement in the shunt region does not function as the memory cell transistor MT or the select transistor ST1, ST2 (functions as a dummy element).

A plurality of the memory blocks BLK are arranged along the second direction in FIG. 2. For the memory blocks BLK arranged adjacent to each other in the second direction, the select transistors ST1 or ST2 are arranged adjacent to each other and share the impurity diffusion layer.

Thus, the impurity diffusion layer formed in the element region AA between the adjacent select gate lines SGD functions as a drain region of the select transistor ST1. A contact plug CP1 is formed on the drain region. The contact plug CP1 is connected to one of the strips of bit lines BL (not shown in the drawings) extending along the second direction. Furthermore, the impurity diffusion layer formed in the element region AA between the adjacent select gate lines SGS functions as a source region of the select transistor ST2. A contact plug CP2 is formed on the source region. The contact plug CP2 is connected to the source line SL (not shown in the drawings).

Each of the following distances is at least double the distance W3 between the adjacent work lines WL; distance W1 between the word line WL and the adjacent select gate line SGD, the distance W1 between the word line WL and the adjacent select gate line SGS, the distance W2 between the adjacent select gate lines SGD, and the distance W2 between the adjacent select gate lines SGS. However, the contact plug CP1 or CP2 is provided between the select gate lines SGD and between the select gate lines SGS. Thus, the distance W2 is normally larger than the distance W1.

Furthermore, each of the select gate lines SGD and SGS includes a connection section EI (Etching Inter-poly). The connection section EI is a region obtained by removing the inter-gate insulating film from the stack gate structure of each of the select transistors ST1 and ST2. The upper gate and the lower gate are connected together via the connection section EI. The connection section EI is shaped like, for example, a rectangle the longitudinal direction of which extends along the first direction.

Contact plugs CP3 and CP4 connected to the select gate lines SGD and SGS, respectively, are provided in the shunt regions. The connection section EI is continuously provided also in the shunt regions. Thus, the contact plugs CP3 and CP4 are provided on the connection sections EI for the select gate lines SGD and SGS. Each of the contact plugs CP3 and CP4 is connected to a shunt wire (not shown in the drawings). The shunt wire is a wire through which row-direction select signals provided by the row decoder 4 are transmitted. The shunt wire is formed of a wiring layer offering a lower resistance than the stack gate structure of each of the select transistors ST1 and ST2. By providing a select signal transmitted through the shunt wire to the stack gate structure of the select transistor ST1 or ST2 in the shunt region, a high speed select operation can be performed.

Furthermore, for example, in a certain block, the contact plugs CP3 and CP4 are alternately provided along the first direction. That is, in a certain shunt region, the contact plug CP3 is provided and not the contact plug CP4. In a shunt region adjacent to the certain shunt region, the contact plug CP4 is provided and not the contact plug CP3.

### <Sectional Configuration>

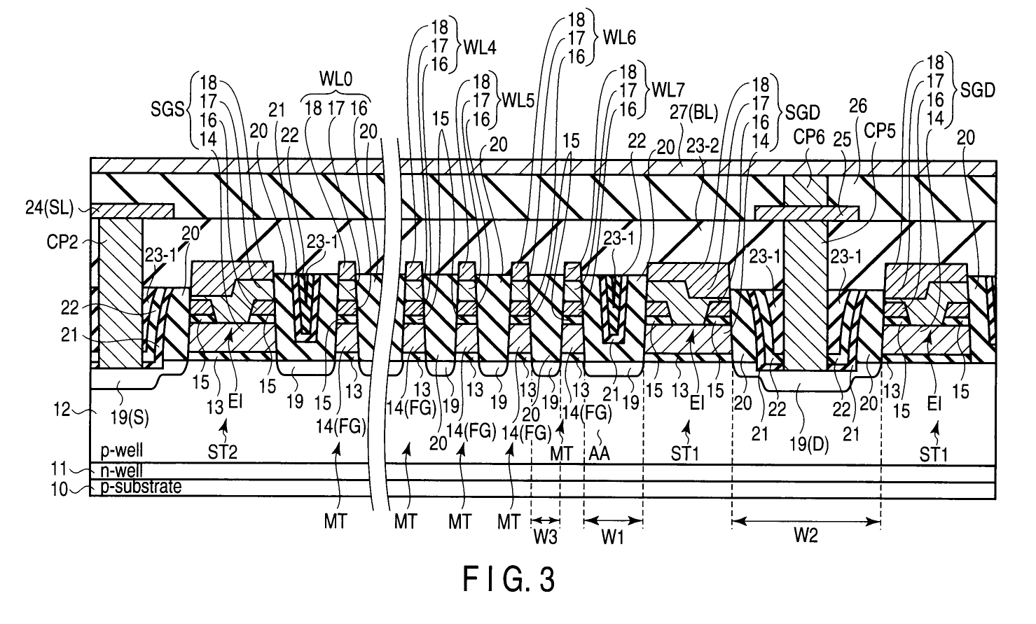

Now, the sectional configuration of the memory cell unit 5 configured as described above will be described with reference to FIG. 3. FIG. 3 is a sectional view taken along line 3-3′ (second direction).

As shown in FIG. 3, an n-type well region 11 is formed in a surface region of a p-type semiconductor substrate 10. A p-type well region 12 is formed in a surface region of the n-type well region 11. Furthermore, a plurality of strips of isolation regions STI (not shown in the drawings) arranged along the second direction are formed in the surface of the p-type well region 12. The region between the adjacent isolation regions STI corresponds to the element region AA.

A gate insulating film 13 is formed on the well region 12 serving as the element region AA. The gate electrodes of the memory cell transistor MT and select transistors ST1 and ST2 are formed on the gate insulating film 13. Each of the gate electrodes of the memory cell transistor MT and select transistors ST1 and ST2 has a polycrystalline silicon layer 14 formed on the gate insulating film 13, an inter-gate insulating film 15 formed on the polycrystalline silicon layer 14, and polycrystalline silicon layer 16 and 17 and a silicide layer 18 sequentially formed on the inter-gate insulating film 15. The inter-gate insulating film 15 is formed of a silicon oxide film, or an ON film, an NO film, an ONO film, or an ONON film which is a stack structure of a silicon oxide film and a silicon nitride film, or a stack structure including any of the ON film, NO film, ONO film, and ONON film, or a stack structure of a TiO₂, HfO₂, Al₂O₃, HfAlOₓ, or HfAlSi film and a silicon oxide or nitride film. Furthermore, the gate insulating film 13 of the memory cell transistor MT serves as a tunnel insulating film.

The polycrystalline silicon layer 14 is divided into pieces for the respective memory cell transistors MT in the first direction so as to function as charge storage layers (floating gates FG). On the other hand, for the polycrystalline silicon layers 16 and 17 and the silicide layer 18, portions of each layer arranged adjacent to each other in the first direction are connected together so as to function as a control gate (word line WL). That is, the crystal silicon layers 16 and 17 and the silicide layer 18 are formed so as to extend over a plurality of the element regions AA while striding over the isolation regions STI. The top surface of the isolation region STI is formed to be lower than that of the polycrystalline silicon layer 14. The inter-gate insulating layer 15 is formed on a side surface of a region of the polycrystalline silicon layer 14 which projects from the surface of the isolation region STI.

For the polycrystalline silicon layers 14, 16, and 17 and silicide layer 18 in the select transistors ST1 and ST2, portions of each layer arranged adjacent to each other in the word line direction are connected together. The polycrystalline silicon layers 14, 16, and 17 and the silicide layer 18 function as the select gate lines SGS and SGD. Each of the select transistors ST1 and ST2 includes the connection section EI having an opening formed by removing parts of the inter-gate insulating film and the polycrystalline silicon layer 16. The polycrystalline layer 14 is connected to the polycrystalline layers 16 and 17 via the connection section EI.

The structure of the select gate lines SGD and SGS in the shunt section is similar to that of the select transistors ST1 and ST2 except that each of the contact plugs CP3 and CP4 is connected to the silicide layer 18 on the connection section EI.

An n-type impurity diffusion layer 19 is formed in the surface of the well region 12 between the gate electrodes. The impurity diffusion layer 19 is shared by the adjacent transistors and functions as a source (S) or a drain (D). Furthermore, the region between the source and the adjacent drain functions as a channel region through which electrons migrate. The gate electrodes, the impurity diffusion layer 19, and the channel region form a MOS transistor corresponding to each of the memory cell transistor MT and select transistors ST1 and ST2.

A silicon oxide material or the like is used to form a side wall insulating film 20 between the adjacent stack gates. The side wall insulating film 20 is completely filled between the stack gates of the memory cell transistors MT.

On the other hand, the side wall insulating film 20 is not completely filled into the region between the stack gates of the memory cell transistor MT and each of the select transistors ST1 and ST2. Instead, the side wall insulating film 20 is provided on and along the side walls of the stack gates and the surface of the impurity diffusion layer 19. Furthermore, in the region between the stack gates of the adjacent select transistors, the side wall insulating film 20 is provided only on the side wall of each of the stack gates. In this region, on the side wall insulating film 20, an insulating film 21 is formed using, for example, TEOS (Tetraethylorthosilicate), and an insulating film 22 is formed using, for example, SiN.

Here, the insulating film 21 is formed to have a film thickness insufficient to fill the region between the memory cell transistor MT and each of the select transistors ST1 and ST2. The insulating film 22 is also formed in the region between the upper layers of the stack gates of the memory cell transistor MT and each of the select transistors ST1 and ST2. If a silicon oxide film or TEOS is used as the side wall insulating film 20 and the insulating film 21 and SiN is used as the insulating film 22, SiN, offering a high dielectric voltage, is formed between the upper layers of the stack gates of the memory cell transistor MT and each of the select transistors ST1 and ST2. This configuration improves a withstand voltage compared to a configuration in which a silicon oxide film or TEOS is used to fill the region between the upper layers of the stack gates of the memory cell transistor MT and each of the select transistors ST1 and ST2.

An interlayer insulating film 23 is formed on the semiconductor substrate so as to cover the memory cell transistors MT, the select transistors ST1 and ST2, and the insulating films 20 to 22. The interlayer insulating film 23 includes an interlayer insulating film 23-1 formed between the select transistors ST1 and ST2, and an interlayer insulating film 23-2 formed on the memory cell transistors MT and the select transistors ST1 and ST2. The interlayer insulating films 23-1 and 23-2 may include the same material or different materials.

The contact plug CP2 reaching the impurity diffusion layer (source) 19 in the source-side select transistor ST2 is formed in the interlayer insulating film 23. A metal wiring layer 24 connected to the contact plug CP2 is formed on the interlayer insulating film 23. The metal wiring layer 24 functions as the source line SL. Furthermore, a contact plug CP5 reaching the impurity diffusion layer (drain) 19 in the drain-side select transistor ST1 is formed in the interlayer insulating film 23. A metal wiring layer 25 connected to the contact plug CP5 is formed on the interlayer insulating film 23. Moreover, the contact plugs CP3 and CP4 (not shown in the drawings) reaching the gate electrodes (silicide layer 18) of the select transistors ST1 and ST2, respectively, are formed in the interlayer insulating film 23. Metal wiring layers (shunt wires; not shown in the drawings) connected to the contact plugs CP3 and CP4, respectively, are formed on the interlayer insulating film 23.

An interlayer insulating film 26 is formed on the interlayer insulating film 23 so as to cover the metal wiring layers 24 and 25. A contact plug CP6 reaching the metal wiring layer 25 is formed in the interlayer insulating film 26. Strips of metal wiring layers 27 are formed on the interlayer insulating film 26; each of the metal wiring layers 27 is connected to a plurality of the contact plugs CP6 and extends along the second direction. The metal wiring layer 27 is formed on the interlayer insulating film 26 so as to lie immediately above the element region AA. The metal wiring layer 27 functions as the bit line BL. Each of the contact plugs CP5 and CP6 and the metal wiring layer 25 corresponds to the contact plug CP1 in FIG. 2.

### <Details of the Sectional Structure>

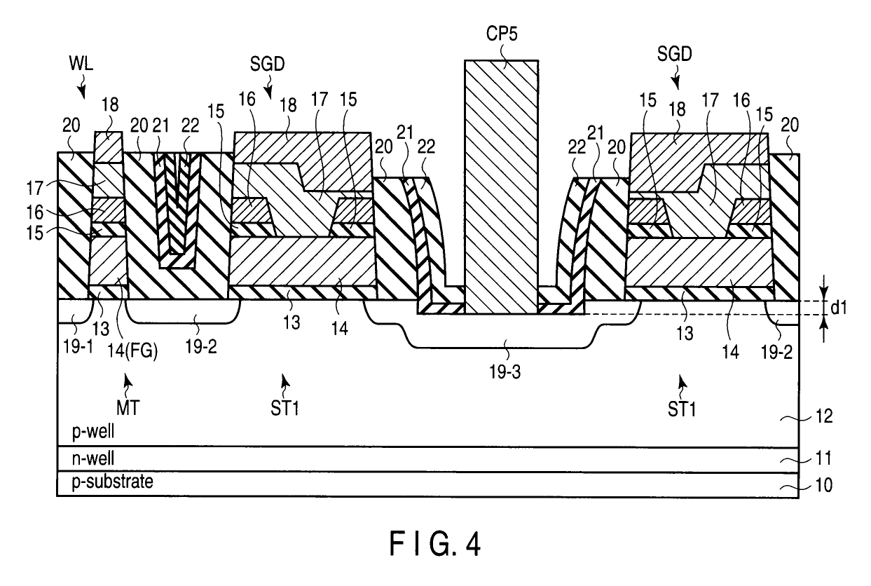

FIG. 4 is an enlarged view of a region shown in FIG. 3 and including the adjacent select transistor ST1. In the description below, the impurity diffusion layer 19 positioned between the stack gates of the adjacent memory cell transistors MT is referred to as an impurity diffusion layer 19-1. The impurity diffusion layer 19 positioned between the stack gates of the memory cell transistors MT and the adjacent select transistor ST1 is referred to as an impurity diffusion layer 19-2. The impurity diffusion layer 19 (drain) positioned between the stack gates of the adjacent select transistors ST1 is referred to as an impurity diffusion layer 19-3.

As shown in the drawings, at least a partial region of the surface of the impurity diffusion layer 19-3 is positioned lower than the channel region surface of the select transistor ST1. That is, the interface between the well region 12 and the gate insulating film 13 is lower than a surface of the impurity diffusion layer 19-2 by a depth d1. That is, the impurity diffusion layer 19-3 has a step on the surface, and the partial region of the impurity diffusion layer 19-3 is recessed. The contact plug CP5 is formed on the recessed region.

On the other hand, the surface of the impurity diffusion layer 19-2 is flush with the impurity diffusion layer 19-1. The surfaces of the impurity diffusion layers 19-1 and 19-2 are flush with the channel region surfaces of the select transistor ST1 and the memory cell transistor MT. That is, the surfaces of the impurity diffusion layers 19-1 and 19-2 is equal to the interface between the well region 12 and the gate insulating film 13.

In other words, the interface between the impurity diffusion layer 19-1 and the side wall insulating film 20 and the interface between the impurity diffusion layer 19-2 and the side wall insulating film 20 are flush with the interface between the semiconductor substrate 10 and the gate insulating film 13. On the other hand, the interface between the impurity diffusion layer 19-3 and the contact plugs CP5 (and the insulating films 21 and 22) is positioned lower than the interface between the semiconductor substrate 10 and the gate insulating film 13.

In other words, the surface of the semiconductor substrate 10 located between the stack gates of the adjacent select transistors ST1 is positioned lower than that located between the stack gates of the memory cell transistor MT and the select transistor ST1. The surface of the semiconductor substrate 10 located between the stack gates of the memory cell transistor MT and the select transistor ST1 is flush with the surface of the semiconductor substrate 10 located between the stack gates of the adjacent memory cell transistors MT.

Moreover, the lower end of the insulating film 22 between the stack gates of the adjacent select transistors ST1 may be positioned lower than that between the stack gates of the memory cell transistor MT and the adjacent select transistor ST1.

The impurity diffusion layer 19-3 is formed deeper than the impurity diffusion layers 19-1 and 19-2. That is, the bottom of the impurity diffusion layer 19-3 is positioned lower than the bottoms of the impurity diffusion layers 19-1 and 19-2. The impurity diffusion layer 19-3 has an LDD structure including a region (extent region) located at a smaller depth from the surface of the semiconductor substrate 10 and a region located at a larger depth from the surface of the semiconductor substrate 10.

The case of the select transistor ST1 has been described with reference to FIG. 4. However, the select transistor ST2 has a similar configuration. That is, in the above description, the impurity diffusion layer 19-3 may be replaced with the source region of the select transistor ST2.

### <Method for Manufacturing the Memory Cell Array 2>

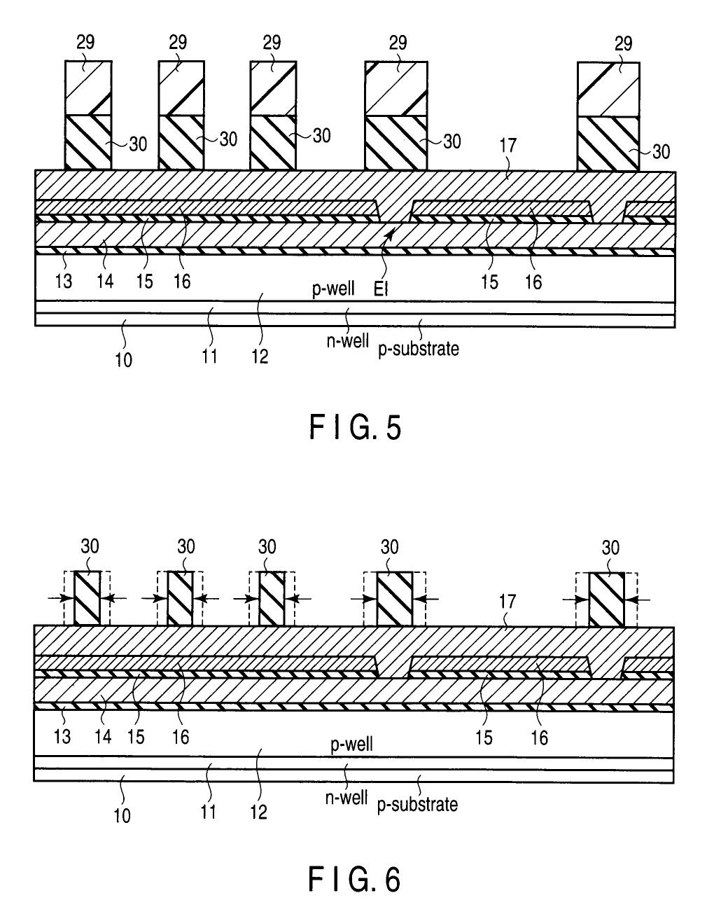

Now, a method for manufacturing the memory cell array 2 configured as described above will be described with reference to FIG. 5 to FIG. 16. FIG. 5 to FIG. 16 are sectional views sequentially showing the steps of manufacturing the memory cell array 2. FIG. 5 to FIG. 16 show a part of the region shown in FIG. 2 and extending along line 3-3′, which part includes the two select gate lines SGD and the word line WL6. A method for manufacturing the select transistor ST2 is not illustrated but is similar to that for manufacturing the select transistor ST1 described below.

As shown in FIG. 5, an n-type well region 11 is formed, by ion implantation, in the surface of a memory cell array 2 formation region of the p-type semiconductor substrate (silicon substrate) 10. Moreover, a p-type well region 12 is formed in the surface of the n-type well region 11.

Subsequently, a silicon oxide film or a silicon oxynitride film is used to form a gate insulating film 13 on the well region 12. Then, a polycrystalline silicon layer 14 is formed on the gate insulating film 13. The polycrystalline silicon layer 14 functions as a charge storage layer in the memory cell transistor MT. The polycrystalline silicon layer 14 is an n-type semiconductor in which n-type impurities containing, for example, phosphorous or arsenic are doped as conductive impurities. The polycrystalline silicon layer 14 may be replaced with, for example, a SiGe layer.

Then, a groove (not shown in the drawings) is formed in a region corresponding to the isolation region STI. Specifically, the polycrystalline silicon layer 14, the gate insulating film 13, and the semiconductor substrate 10 are sequentially etched. Thus, a groove for formation of an isolation region STI is formed in self-alignment with the polycrystalline silicon layer 14. Thereafter, an insulating film (silicon oxide film) is buried inside the groove to form an isolation region STI. At this time, the surface of the insulating film is etched back such that the top surface of the insulating film is lower than that of the polycrystalline silicon layer 14.

Then, a inter-gate insulating film 15 having a silicon oxide film or a three-layer structure of a silicon oxide film, a silicon nitride film, and a silicon oxide film is deposited all over the surface of the polycrystalline silicon layer 14. Subsequently, a polycrystalline silicon layer 16 is deposited all over the surface of the inter-gate insulating film 15.

Then, a connection section EI is formed by a photolithography technique and anisotropic etching such as RIE (Reactive Ion Etching). That is, the polycrystalline silicon layer 16 and the inter-gate insulating film 15 are removed from a part of a region in which select transistors ST1 and ST2 are to be formed. As a result, the connection section EI is formed such that the polycrystalline silicon layer 14 is exposed in the connection section EI.

Thereafter, a polycrystalline silicon layer 17 is deposited on the polycrystalline silicon layer 16 and on the polycrystalline silicon layer 14 exposed in the connection section EI. The polycrystalline silicon layer 17 is an n-type semiconductor in which n-type impurities containing, for example, phosphorous or arsenic are doped as conductive impurities. The polycrystalline silicon layer 17 is formed in contact with the polycrystalline silicon layer 14 by being filled into the opening in the connection section EI.

Then, a mask is formed for etching for formation of stack gates. A shown in FIG. 5, an insulating film (sacrificial hard mask) 30 such as a silicon oxide film or a silicon nitride film is formed on the polycrystalline silicon layer 17. A photo resist 29 is applied onto the insulating film 30. Then, the photolithography technique is used to pattern the photo resist 29 in the form of strips extending along the second direction. Thereafter, the insulating film 30 is patterned by anisotropic etching such as RIE using the photo resist 29 as a mask.

The above-described steps result in the configuration shown in FIG. 5.

The photo resist 29 is removed by ashing or the like. Thereafter, the insulating film 30 is slimmed by, for example, isotropic etching. The line width of the resulting insulating film 30 is equal to the distance W3 between the adjacent word lines in the region in which the memory cell transistors MT are to be formed. Furthermore, in the region in which the select transistor ST1 and ST2 are to be formed, the line width of the resulting insulating film 30 is smaller than that of each of the select gate lines SGD and SGS.

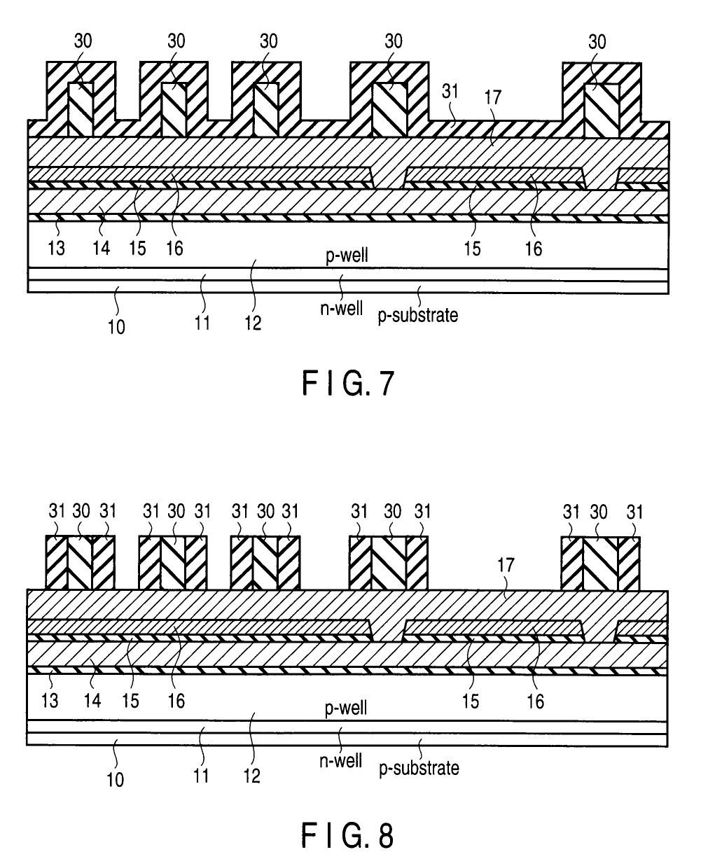

As shown in FIG. 7, an insulating film 31, for example, a silicon oxide film or a silicon nitride film, is formed on the polycrystalline silicon layer 17 and the insulating film 30. The insulating film 31 has only to be made of a material that provides a sufficient etching selection ratio for the insulating film 30 and the polycrystalline silicon layer 17. Furthermore, the film thickness of the insulating film 30 is set equal to the target line width for the word line WL.

As shown in FIG. 8, anisotropic etching such as RIE is used to remove the insulating film 31 formed on the top surface of the insulating film 30 and on the polycrystalline silicon layer 17, with the insulating film 31 remaining only on the side surface of the insulating film 30. At this time, the region located immediately above the connection section EI is covered with the insulating films 30 and 31.

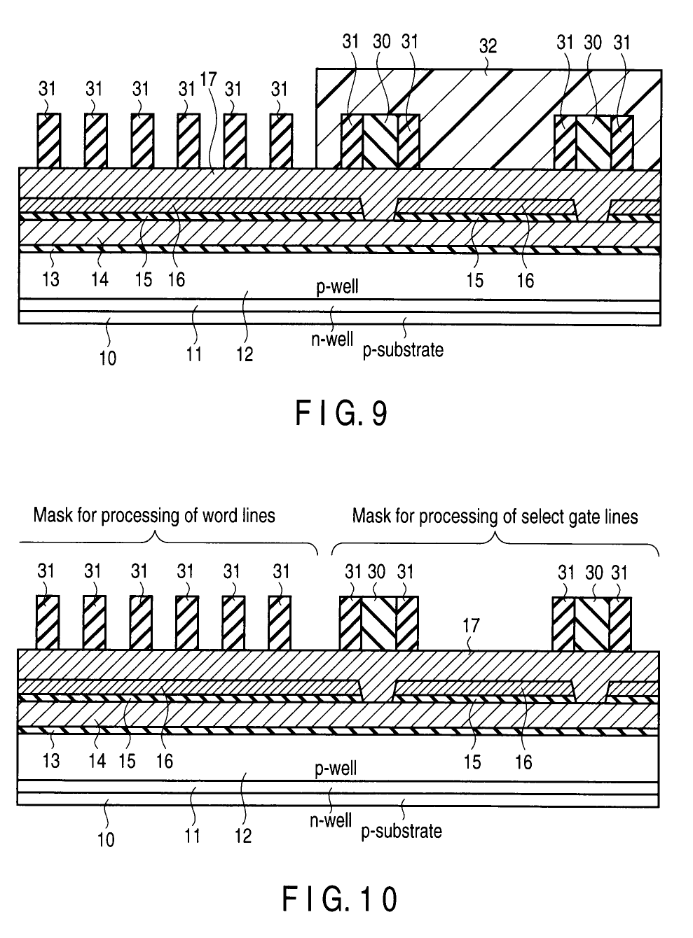

As shown in FIG. 9, the region in which the select transistors ST1 and ST2 are to be formed is covered with, for example, a photo resist 32. Wet etching is then carried out with the insulating films 30 and 31 in the region in which the select transistors ST1 and ST2 are to be formed, protected by the photo resist 32. Thus, the insulating film 30 in the region in which the memory cell transistors MT are to be formed is removed, with the insulating film 31 left in the region.

Thereafter, the photo resist 32 is removed. As a result, as shown in FIG. 10, a mask is completed which is formed of the insulating layers 30 and 31 and used to form the stack gates of the memory cell transistors MT and the select transistors ST1 and ST2. At this time, the mask is formed such that the distance between a select gate line and the adjacent word line is more than double the distance between adjacent word lines.

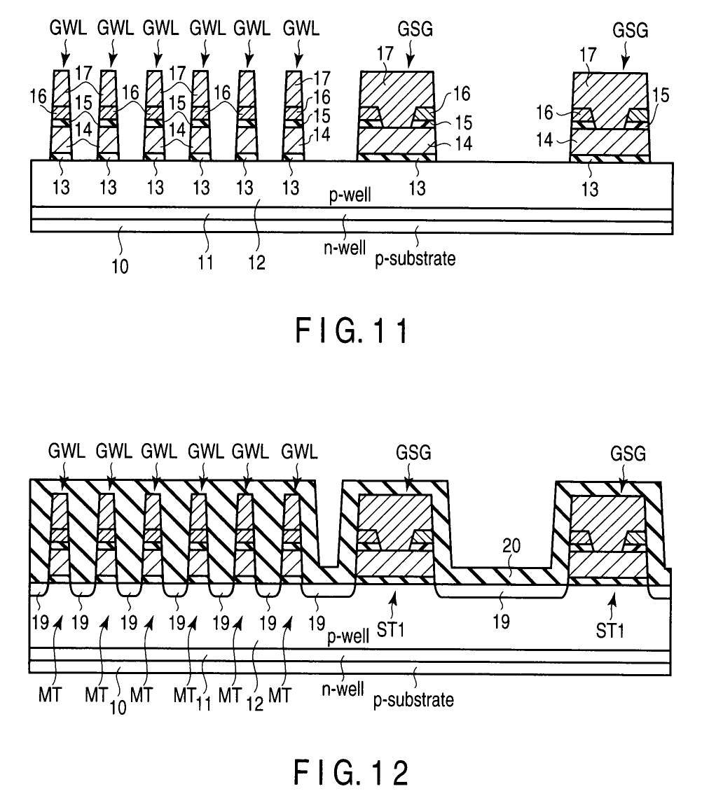

Then, the polycrystalline silicon layers 17 and 16, the inter-gate insulating film 15, the polycrystalline silicon layer 14, and the gate insulating film 13 are patterned in the form of strips extending along the first direction, by an anisotropic etching such as RIE using the mask shown in FIG. 10. As a result, as shown in FIG. 10, stack gates GWL of the memory cell transistors MT and stack gates GSG of the select transistors ST1 and ST2 are completed. At this time, the connection section EI is included in the stack gates GSG by this etching. Thereafter, the mask (the insulating film 30 and 31) is removed. As a result, a structure shown in FIG. 11 is obtained.

As shown in FIG. 12, n-type impurity ions are implanted through the stack gates GWL and GSG as a mask. As a result, an impurity diffusion layer 19 is formed in the surface of the well region 12, thus completing memory cell transistors MT. The impurity diffusion layer formed during the present step corresponds to an extent region of an LDD structure in the select transistors ST1 and ST2.

As shown in FIG. 12, for example, a silicon oxide film (TEOS film) is used to form an insulating film 20 covering the top and side surfaces of the stack gates GWL and GSG. At this time, the film thickness of the insulating film 20 is at least 3/2×W1. Then, since the distance between the stack gates GWL is 3, the region between the stack gates GWL is completely filled with the insulating film 20. In contrast, the region between the stack gates GWL and GSG and the region between the stack gates GSG are not completely filled with the insulating film 20. The insulating film 20 is formed along the side walls of the stack gates GWL and GSG and the surface of the impurity diffusion layer 19 in the region between the stack gates GWL and GSG and the region between the stack gates GSG.

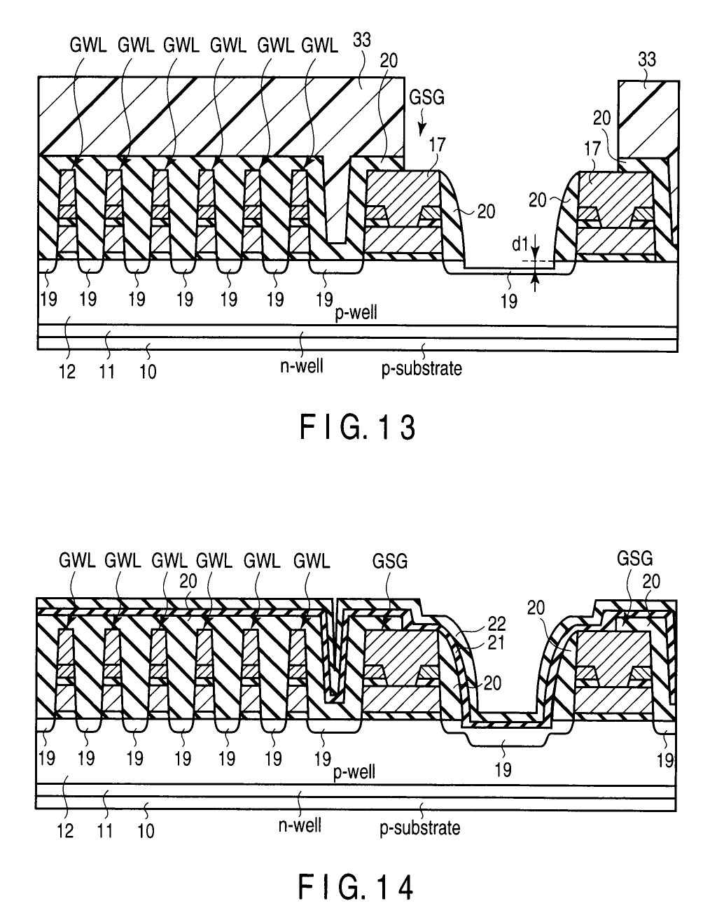

As shown in FIG. 13, a photo resist 33 is applied onto the insulating film 20. An opening is formed in the region between the stack gates GSG by the photolithography technique. At this time, the opening is formed such that the end of the photo resist is positioned on the stack gate GSG. Then, the insulating film 20 is etched by RIE or the like through the photo resist 33 as a mask. As a result, in the region between the stack gates GSG, the insulating film 20 remains only on the side walls of the stack gates GSG. Then, the side wall insulating film 20 is formed. Furthermore, in the opening, the polycrystalline silicon layer 17 in the stack gate GSG is exposed. At this time, the surface of the impurity diffusion layer 19 between the stack gates GSG is partly etched. Thus, the surface of the impurity diffusion layer 19 is partly deeper than the channel region surface of the select transistor ST1 by d1.

As shown in FIG. 14, the photo resist 33 is removed. N-type impurities are doped into the well region 12 through the stack gates GWL and GSG and the insulating film 20 as a mask. As a result, the impurity diffusion layer 19 as the drain region of the select transistor ST1 is formed. In the present step, the drain of the select transistor ST1 is formed deeper than the source of the select transistor ST1 and the source and drain of the memory cell transistor MT.

As shown in FIG. 14, a silicon oxide film (TEOS film) or the like is used to form an insulating film 21 on the insulating film 20 and on the region exposed by the etching in FIG. 13. Moreover, a silicon nitride film or the like is used to form an insulating film 22 on the silicon oxide film 21. The insulating film 22 functions as an anti-oxidant film to prevent an oxidant from infiltrating to a region below the insulating film 21. The insulating film 20 is not present between the stack gates GSG except on the side wall portions of the stack gates GHG. Thus, the lower end of the insulating film 22 is positioned lower between the stack gates GSG than between the stack gates GWL and GSG, by a depth equal to the sum of the thickness of the insulating film 20 and the depth d1 of a step formed in the impurity diffusion layer 19.

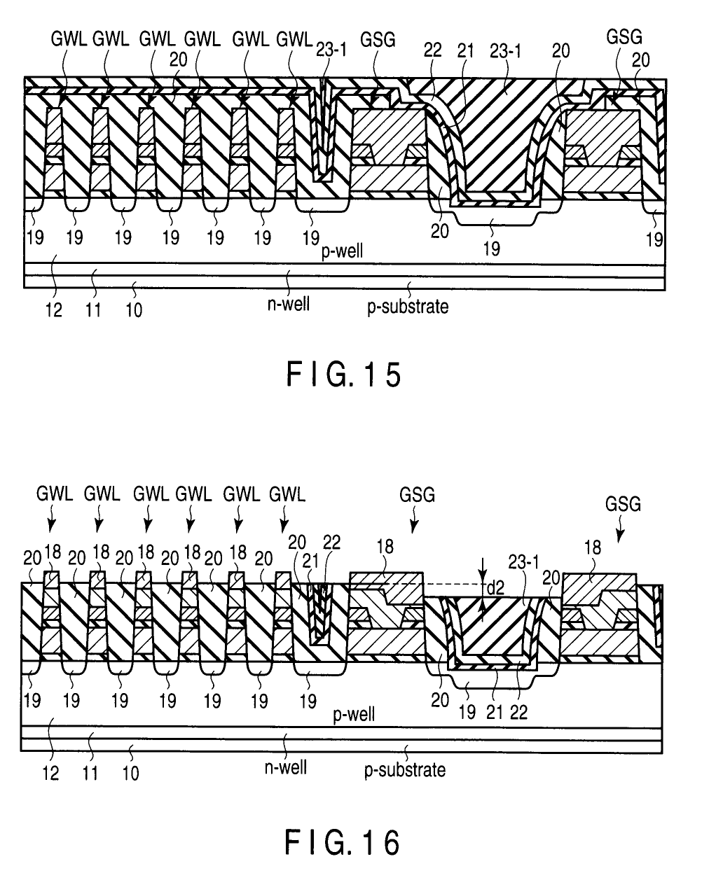

As shown in FIG. 15, for example, an interlayer insulating film 23-1 (e. q. BPSG) all over the resulting structure. Thereafter, the interlayer insulating film 23-1 is flattened by a CMP method using the insulating film 22 as a stopper.

As shown in FIG. 16, the insulating films 20 to 22 are partly etched by RIE or the like to expose the top surfaces of the stack gates GWL and GSG. At this time, the insulating film 20 is not present in a partial region on the stack gate GSG. Thus, as a result of etching, the top surface of the insulating films 20 to 22 between the stack gates GSG is lower than the top surface of the insulating films 20 to 22 between the stack gates GWL and GSG and the top surface of the insulating film 20 between the stack gates GWL, by d2. In FIG. 16, the top surface of the interlayer insulating film 23-1 aligns with the top surface of the insulating films 20 to 22. However, in connection with the etching rate, the top surface of the interlayer insulating film 23-1 may be lower than the top surface of the insulating films 20 to 22.

Subsequently, a metal layer such as tungsten is formed all over the surface of the resulting structure, which is then subjected to a thermal treatment to silicidize the surface of the polycrystalline silicon layer 17. Thus, a silicide layer 18 is formed. In the present step, the whole polycrystalline silicon layer 17 may be silicidized.

Thereafter, interlayer insulating films, contact plugs, and metal wiring layers are formed by well-known techniques to complete the structure shown in FIG. 3. Only the select transistor ST1 has been described. However, the select transistor ST2 is formed by a similar method. In this case, the impurity diffusion layer 19 between the stack gates GSG functions as the source of the select transistor ST2.

### <Effects>

The NAND flash memory according to the present embodiment allows effects (1) and (2) described below to be exerted.

(1) The reliability of the NAND flash memory can be improved.

With increasing miniaturization of NAND flash memory, there is a demand for a patterning technique allowing the limit of the current photolithography technique to be exceeded. Particularly for the word line WL, there is a demand to make the size smaller than the minimum processing size achieved by the photolithography technique.

To meet the demand, for example, the double patterning technique described above in the embodiment with reference to FIG. 5 to FIG. 10 can be used. The double patterning technique is as follows. First, a normal photolithography technique is used to transfer a resolved pattern to a sacrificial hard mask (insulating film 30) (see FIG. 5). Then, a material (insulating material 31) to be formed into a new hard mask is deposited. The resulting film is then anistropically etched so as to be left only on the side wall of the sacrificial hard mask (see FIGS. 7 and 8). Thereafter, the sacrificial hard mask is removed (see FIG. 9). The remaining new hard mask is then used as a mask (see FIG. 10).

According to the present method, the film thickness of the insulating film 31 corresponds directly to the size of the mask. Thus, reducing the film thickness of the insulating film 31 enables a mask with a size smaller than the minimum processing size by the photolithography technique.

However, according to the present technique, the line size is determined by the film thickness of the hard mask material. Thus, forming a mask patterned so as to have a width different from the film thickness is very difficult. That is, using the present technique to form a mask with a plurality of line sizes is difficult. For example, the line width of the select gate line is different from that of the word line. It is thus difficult to use the double patterning technique to form a mask for select gate lines and a mask for word lines during the same step.

Consequently, to allow a mask with a plurality of line sizes to be formed, different masks need to be produced. A pattern left on the side wall of the sacrificial hard mask and having a size equal to or smaller than the minimum processing size by the photolithography technique is hereinafter referred to as a side wall pattern (a mask 31 for processing of word lines in FIG. 10). A different pattern that is wider than the side wall pattern is hereinafter referred to as a wider pattern (masks 30, 31 for processing of select gate lines in FIG. 10).

The technique according to the present embodiment produces the side wall pattern and the wider pattern differently as described below. That is, when the sacrificial hard mask 30 is removed with the insulating film 31 left, a wider-pattern formation region (the region in which the select transistors are to be formed) is masked using a photo resist or the like (see FIG. 9). Thus, the sacrificial hard mask 30 is left in the wider pattern so that the wider pattern is formed of the sacrificial hard mask 30 and the insulating film 31.

Thereafter, the sacrificial hard mask is removed by wet etching. Thus, the photo resist 32 needs to completely cover the entire region of the wider pattern. This is because if even a small part of the winder pattern is exposed from the photo resist 32, an etchant for the wet etching infiltrates into the wider pattern to cause the wider pattern to lose shape.

In this case, however small the boundary region between the side wall pattern and the wider pattern can be formed is determined by the profile and alignment precision of the photo resist. In the memory cell array in the NAND flash memory, the region between the select gate line and the word line (SG-WL) corresponds to the boundary region.

Here, when the resolution limit of lithography is, for example, 80 nm, the side wall pattern has a line space of about 40 nm, which is smaller than the resolution limit of lithography. Furthermore, in view of an alignment margin of about 40 nm for the resolution limit of lithography, 80 nm, the boundary region needs to have a line space of, for example, at least 120 nm. As a result, the distance between SG and WL is several times as long as that between the adjacent word lines (WL-WL). This is in contrast with the previous generations of NAND flash memories, which do not require the double patterning technique and in which the distance between WL and WL is equal to that between SG and WL.

When the distance between SG and WL is larger than that between WL and WL as described above, the following problem may occur. As shown in FIG. 12, the insulating film 20, serving as the side wall insulating film, is formed on the side walls of the word lines and the select gate lines. This is to allow the select transistors to have the LDD (Lightly Doped Drain) structure (see FIG. 14). Thus, in order to allow the characteristics of the select transistors to be controlled, the thickness of the insulating film 20 should be precisely controlled. Thus, in the structure in which the allowed distance between SG and WL is several times as long as the distance between WL and WL, it may be very difficult to set the film thickness of the insulating film 20 to such a value as provides the select transistors with the desired characteristics and enables the region between SG and WL to be completely filled. This relates to the sectional shape and alignment precision of the resist during photolithography, which may affect the different production of the side wall pattern and the wider pattern, as well as the resolution margin of the pattern to be transferred to the sacrificial hard mask. In this case, the region between SG and WL is not completely filled with the insulating film 20 as shown in FIG. 12.

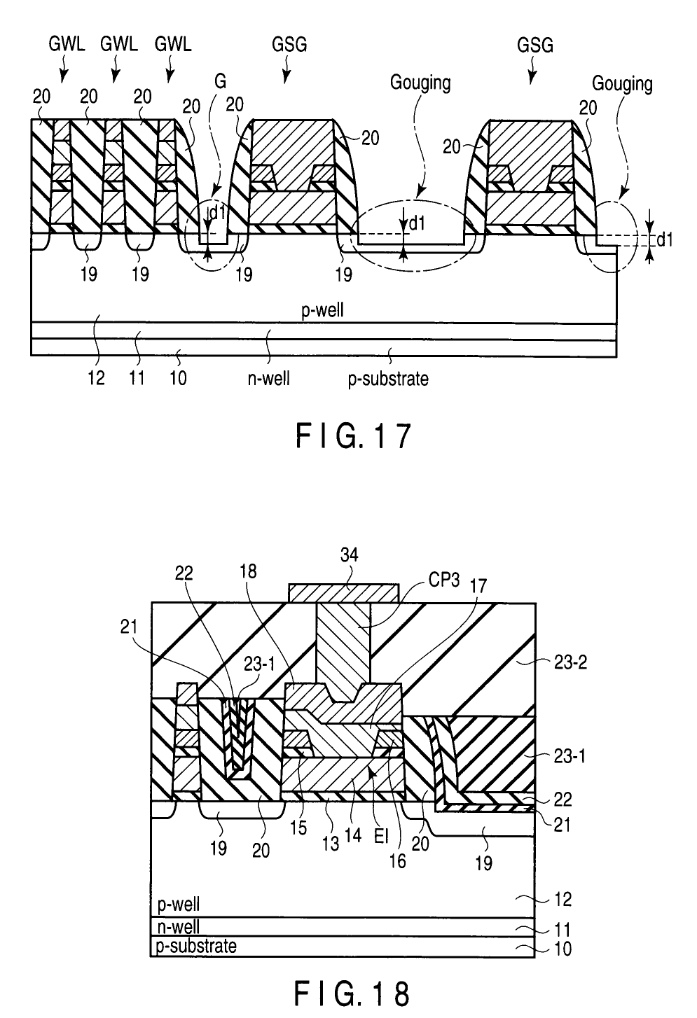

Thus, in the configuration shown in FIG. 12, when the insulating film 20 is etched, the silicon substrate 10 is etched between SG and WL. This is shown in FIG. 17. FIG. 17 shows a configuration obtained by etching the insulating film 20 in FIG. 12. As shown in FIG. 17, the silicon substrate 10 is etched not only between SG and SG but also between SG and WL. The etched surface is lower than the surface of the channel region in the select transistor by d1. This etching of the silicon substrate 10 is hereinafter referred to as “gouging”. The gouging increases the S factor of the select transistor and of the memory cell transistor located adjacent to the select transistor, and reduces a cell current. As a result, the characteristics of the NAND flash memory may be degraded.

In contrast, in the NAND flash memory according to the present embodiment, during the step of etching the insulating film 20, the photo resist 33 protects the region in which memory cell transistors MT are to be formed, that is, the side wall pattern formation region, and the above-described boundary region (see FIG. 13). This prevents possible gouging between SG and WL. Even if the distance between SG and WL is long, the characteristics of the select transistors can be prevented from being degraded, with the film thickness of the side wall insulating film 20 set to the optimum value for formation of the LDD structure.

On the other hand, the impurity diffusion layer 19 between the select gates is formed by ion implantation after the occurrence of gouging. That is, the impurity diffusion layer 19 is formed deeper than the source of the select transistor ST1 and the source and drain of the memory cell transistor MT. Provided that the bottom of the contact plug CP5 is located at least above the lower surface (bottom surface) of the impurity diffusion layer 19 between the select gates, the possibility of short circuiting from the contact plug CP5 to the p-type well region 12 is prevented. Thus, the occurrence of gouging poses no problem. This also applies to the contact plug CP2.

Furthermore, the memory cell transistors MT and the select transistors ST1 and ST2 are covered with the anti-oxidant film 22 such as an SiN film as described with reference to FIG. 14. In this case, the surface of the impurity diffusion layer 19 between SG and WL is separate from the anti-oxidant film 22 by a distance corresponding to the film thickness of the insulating films 20 and 21. This enables a reduction in the impact of fixed charges resulting from the anti-oxidant film 22 on the element region AA in the memory cell unit.

(2) The operating speed of the NAND flash memory can be increased.

In the configuration according to the present embodiment, during the silicide step, the top surface of the insulating films 20 to 22 on the drain-side side wall portion of the stack gate of the select transistor ST1 is set to be lower than the source-side top surface of the insulating films 20 to 22 and the top surface of the insulating film 20 on the side wall of the memory cell transistor MT (see FIG. 16). More specifically, the former top surface is set to be lower than the latter top surfaces by a depth corresponding to the film thickness of the insulating film 20. This also applies to the select transistor ST2.

Thus, the stack gate GSG of the select transistor is silicidized deeper from the surface than the stack gate of the memory cell transistor MT. This enables a reduction in the resistance of the select gate lines SGD and SGS and in the operating speed of the NAND flash memory.

Furthermore, forming the silicide layer 18 deeper also produces the following effects. FIG. 18 is a sectional view showing the select gate line SGD in the shunt region and taken along the bit line direction. As shown in FIG. 18, in the shunt region, the contact plug CP3 contacting the silicide layer 18, a part of the select gate line SGD is formed in the interlayer insulting film 23. A metal wiring layer 34 connected to the contact plug CP3 and serving as a shunt wire for the select gate line SGD is formed on the interlayer insulating film 23. Although not shown in the drawings, this also applies to the select gate line SGS.

The contact plug CP3 is formed by using the silicide layer 18 as a stopper to form a contact hole reaching the silicide layer 18 in the interlayer insulating film 23, and thereafter filling the interior of the contact hole with a conductive film. The contact plug CP3 is positioned immediately above the connection section EI.

In this case, since the polycrystalline silicon layer 17 fills the connection section EI, the top surface of the polycrystalline silicon layer 17 may be recessed. As a result, as shown in FIG. 18, the top surface of the silicide layer 18 is also recessed. Therefore, if the film thickness of the silicide layer 18 is insufficient, the silicide layer 18 fails to function sufficiently as a stopper. Thus, the contact hole may penetrate the silicide layer 18.

In contrast, in the configuration according to the present embodiment, the silicide layer 18 in each of the select gate lines SGD and SGS is formed sufficiently deeper. This is particularly effective if the bottom of the contact plug CP3 is formed on a thick portion of the silicide layer 18 by adjusting the temperature and duration of the thermal treatment or if the formation position of the contact plug CP3 and the silicide layer 18 is placed away from the center of the select gate line SGD or SGS so that the bottom of the contact plug CP3 is formed on thick portions of the connection section EI and the silicide layer 18. This enables not only a reduction in the resistance value of the select gate line but also an increase in the process margin for formation of the contact plug CP3 (CP4).

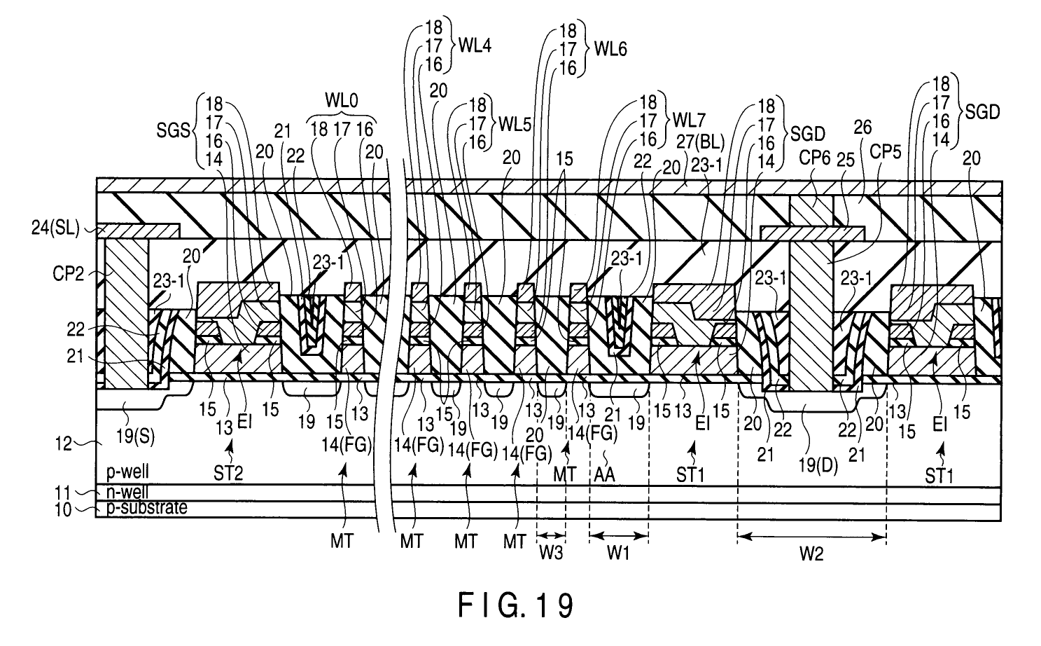

In the above-described embodiment, in the patterning step shown in FIG. 11, the gate insulating film 13 is also etched. However, in the present step, the gate insulating film 13 may be left. The structure of a memory cell array obtained in this case is shown in FIG. 19. FIG. 19 is a sectional view taken along line 3-3′ in FIG. 2. As shown in FIG. 19, the gate insulating film 13 is positioned immediately below not only the stack gates but also the side wall insulating film 20. In this case, the anti-oxidant film 22 between SG and WL is separate from the surface of the impurity diffusion layer 19 by a depth corresponding to the gate insulating film 13 and the insulating films 20 and 21.

### Second Embodiment

Now, a semiconductor memory device and a method for manufacturing the semiconductor memory device according to a second embodiment of the present invention will be described. The present embodiment relates to the structure of a peripheral transistor according to the above-described first embodiment. Differences from the first embodiment will not be described below.

### <Sectional Structure of the Peripheral Transistor>

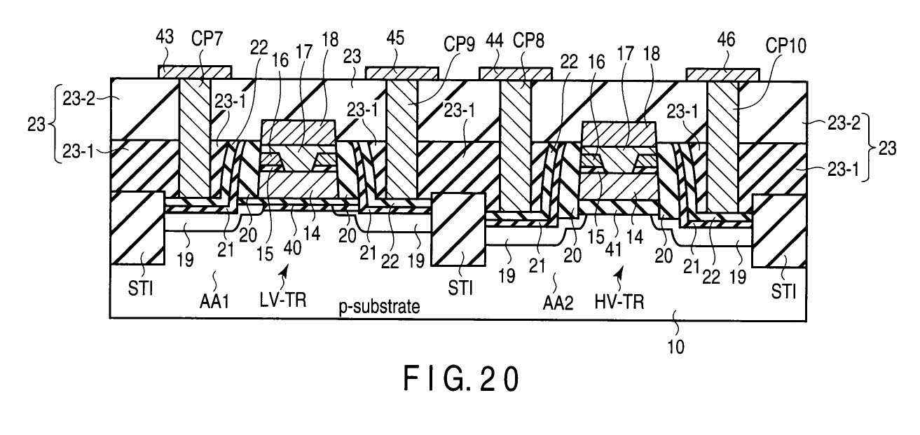

The peripheral transistor according to the present embodiment will be described with reference to FIG. 20. FIG. 20 is a sectional view of the peripheral transistor taken along a gate length direction. In the description below, a low-withstand-voltage n-channel MOS transistor LV-TR and a high-withstand-voltage n-channel MOS transistor HV-TR will be taken as examples.

The MOS transistor HV-TR transfers a program voltage VPGM (for example, 20 V), an intermediate voltage VPASS (<VPGM), and the like in, for example, a row decoder 4. The program voltage VPGR is applied to a selected word line during data programming. The program voltage VPGR is a high voltage required to inject electrons into a charge storage layer by FN tunneling. Furthermore, the intermediate voltage VPASS is applied to unselected word lines during data programming. The intermediate voltage VPASS turns on the memory cell transistor T regardless of the data held in the memory cell transistor MT.

On the other hand, the MOS transistor LV-TR offers a lower breakdown voltage than the MOS transistor HV-TR. For example, in the row decoder 4, the MOS transistor LV-TR is used in a circuit decoding a row address signal RA. The MOS transistor LV-TR operates using, for example, an external voltage Vcc (for example, 1.5 V) as a power supply voltage. The program voltage VPGM and the intermediate voltage VPASS are obtained by raising the external voltage Vcc.

As shown in FIG. 20, isolation regions STI are formed in the surface of the semiconductor substrate 10. Element regions AA1 and AA2 are each provided so as to be surrounded by the isolation regions STI. The MOS transistor LV-TR is formed on the element region AA1. The MOS transistor HV-TR is formed on the element region AA2.

The MOS transistor LV-TR includes a stack gate formed on gate insulating films 40. The MOS transistors HV-TR includes a stack gate formed on gate insulating films 41. The structure of the stack gate is similar to that of the stack gate of each of the select transistors ST1 and ST2 in the memory cell array 2. To obtain a high breakdown voltage, the gate insulating film 41 in the MOS transistor HV-TR has a larger film thickness than the gate insulating film 40 in the MOS transistor LV-TR.

An impurity diffusion layer 19 is formed in the surface of the semiconductor substrate 10 to function as the source and drain of each of the MOS transistors LV-TR and HV-TR. Unlike in the case of the select transistors ST1 and ST2, in the MOS transistors LV-TR and HV-TR, both the source and drain have the LDD structure.

The MOS transistors LV-TR and HV-TR are configured as described above. As is the case with the select transistors ST1 and ST2, gouging occurs in the MOS transistors LV-TR and HV-TR. That is, the surface of the impurity diffusion layer 19 in the MOS transistor LV-TR is positioned lower than the surface of the channel region in the MOS transistor LV-TR. That is, the surface of the impurity diffusion layer 19 in the MOS transistor LV-TR is lower than the interface between the semiconductor substrate 10 and the gate insulating film 40, by d1.

Furthermore, in the MOS transistor HV-TR, the surface of an LDD region (a shallower region of the impurity diffusion layer 19) is positioned lower than the surface of the channel region in the MOS transistor HV-TR. That is, the surface of an LDD region is lower than the interface between the semiconductor substrate 10 and the gate insulating film 41. Moreover, the surface of a deeper region of the impurity diffusion layer 19 is positioned lower than the surface of the LDD region by d1.

A side wall insulating film 20 and insulating films 21 and 22 are formed on the side wall of each of the MOS transistors LV-TR and HV-TR as is the case with the select transistors ST1 and ST2. An interlayer insulating film 23 is formed on the semiconductor substrate 10 so as to cover the MOS transistors LV-TR and HV-TR. Moreover, contact plugs CP7, CP8, CP9, and CP10 are formed in interlayer insulating film 23; the contact plugs CP7 and CP8 are connected to the drains of the MOS transistors LV-TR and HV-TR, respectively, and the contact plugs CP9 and CP10 are connected to the drains of the MOS transistors LV-TR and HV-TR, respectively. Metal wiring layers 43 to 46 connected to the contact plugs CP7 to CP10, respectively, are formed on the interlayer insulating film 23.

Although not shown in the drawings, the above description also applies to p-channel MOS transistors. In this case, an n-type well region is formed in the surface of the semiconductor substrate 10. A peripheral MOS transistor is formed on the n-type well region.

### <Method for Manufacturing the MOS Transistors LV-TR and HV-TR>

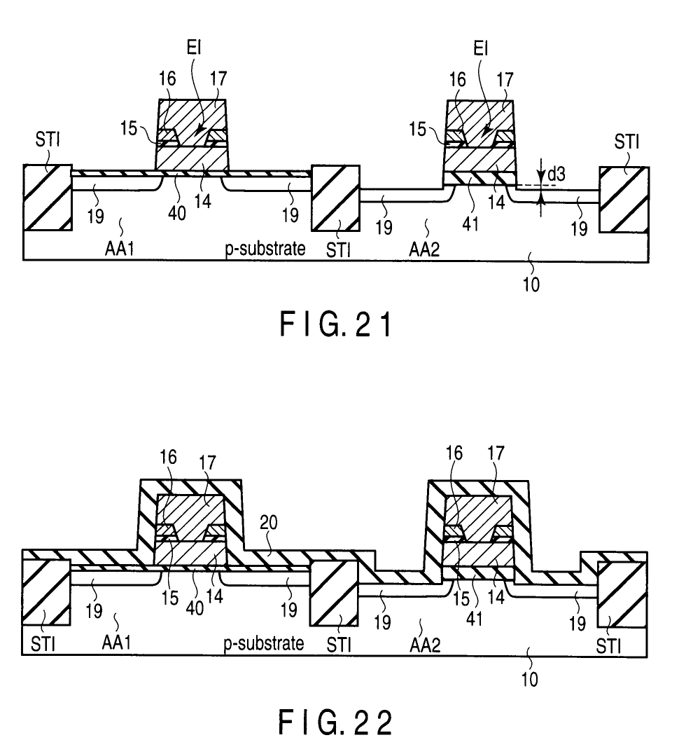

Now, a method for manufacturing the MOS transistors LV-TR and HV-TR configured as described above will be described with reference to FIG. 21 to FIG. 25. FIG. 21 to FIG. 25 are sectional views sequentially showing the steps of manufacturing the MOS transistors LV-TR and HV-TR. FIG. 21 to FIG. 25 show a section taken along a channel length direction. In the description below, the MOS transistors LV-TR and HV-TR are formed simultaneously with the memory cell array 2. The method for manufacturing the MOS transistors LV-TR and HV-TR is basically the same as that for manufacturing the select transistors ST1 and ST2 described in the first embodiment.

Isolation regions STI are formed in the semiconductor substrate 10. Element regions AA1 and AA2 are then formed in which the MOS transistors LV-TR and HV-TR, respectively are to be formed. Then, a gate insulating film 40 is formed on the element region AA1. A gate insulating film 41 is formed on the element region AA2. The film thickness of the gate insulating film 41 is larger than that of the gate insulating film 40 and is equal to or larger than that of a gate insulating film 13. Then, in the step in FIG. 5 described in the first embodiment, a polycrystalline silicon layer 13, an inter-gate insulating film 15, polycrystalline silicon layers 16 and 17, a sacrificial hard mask 30, and a photo resist 29 are sequentially formed on the gate insulating films 40 and 41. Furthermore, a connection section EI is formed in the region in which the MOS transistors LV-TR and HV-TR are to be formed.

Then, the sacrificial hard mask 30 is patterned, and the steps described with reference to FIG. 6 to FIG. 10 are carried out to complete a mask for formation of the gate electrodes of the MOS transistors LV-TR and HV-TR. The mask includes insulating layers 30 and 31 similarly to the mask for formation of the select transistors ST1 and ST2. Obviously, during the step in FIG. 9, the region in which the MOS transistors LV-TR and HV-TR are to be formed is protected by the photo resist 32.

The gate electrodes of the MOS transistors LV-TR and HV-TR is formed by REE using resulting mask, as shown in FIG. 21. The respective gate electrodes are formed during different etching steps. The gate electrode of the MOS transistor LV-TR is hereinafter referred to as GLV. The gate electrode of the MOS transistor HV-TR is hereinafter referred to as GHV. As shown in FIG. 21, during the formation of the gate electrode GHV, etching continues until the surface of the semiconductor substrate 10 is reached. This is because, for the ion implantation step for forming an LDD region, the gate insulating film 41, which has a large film thickness, is preferably removed. As a result, in the element region AA2, gouging occurs to a depth d3.

On the other hand, during formation of the gate electrode GLV, etching is stopped at the surface of the gate insulating film 40. Thus, no gouging occurs in the element region AA1. Of course, even during formation of the gate electrode GLV, etching may continue until the semiconductor substrate 10 is reached.

Thereafter, n-type impurities are ion-implanted in the surface of the semiconductor substrate 10 through the gate electrodes GLV and GHV as a mask. Thus, a shallow impurity diffusion layer 19 corresponding to the MOS transistors LV-TR and HV-TR is formed to obtain the configuration in FIG. 21.

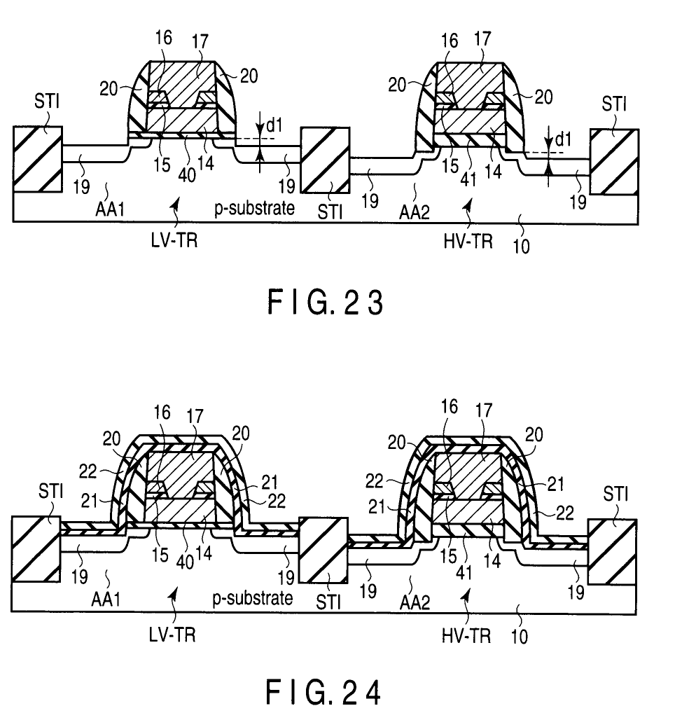

As shown in FIG. 22, the step in FIG. 12 described in the first embodiment is carried out to form an insulating film 20 on the formation region for the MOS transistors LV-TR and HV-TR. As shown in FIG. 23, the step in FIG. 13 described in the first embodiment is carried out. That is, a photo resist 33 is applied onto the entire surface of the resulting structure. The regions other than memory cell transistors MT formation regions are opened. At this time, the photo resist 33 in the formation region for the MOS transistors LV-TR and HV-TR is also removed. Then, the insulating film 20 is etched through the photo resist 33 as a mask. As a result, in the formation region for the MOS transistors LV-TR and HV-TR, the insulating film 20 remains only on the side walls of the gate electrodes GLV and GHV. At this time, as is the case with the region between SG and SG, the surface of the impurity diffusion layer 19 in the MOS transistors LV-TR and HV-TR is gouged. The amount of gouging in this case is almost equal to that in the case of the region between SG and SG, and corresponds to the depth d1. Thereafter, n-type impurities are doped into the semiconductor substrate 10 through the gate electrodes GLV and GHV as a mask. As a result, the source and drain of each of the MOS transistors LV-TR and HV-TR is completed.

Furthermore, since the n-type impurities are doped into the semiconductor substrate 10 through the gate electrodes GLV and GHV as a mask, the impurity diffusion layer 19 in the MOS transistors LV-TR and HV-TR is formed deeper than the source of the select transistor ST1 and the source and drain of the memory cell transistor MT. Provided that at least the bottom of the contact plugs CP9 and CP10 is located above the lower surface (bottom surface) of the impurity diffusion layer 19, the possibility of short circuiting from the contact plugs CP9 and CP10 to the semiconductor substrate 10 is prevented. Thus, the occurrence of gouging poses no problem.

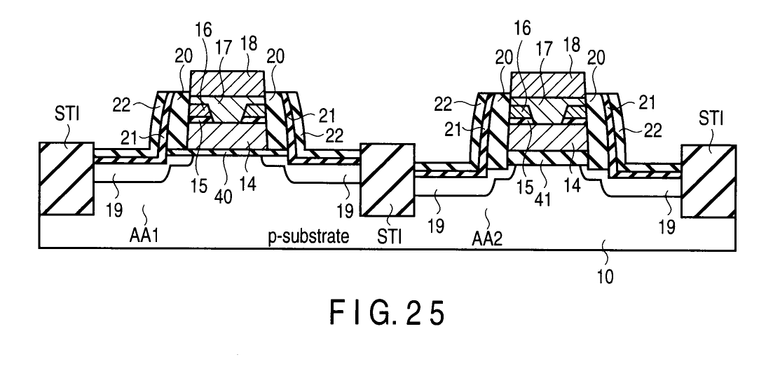

As shown in FIG. 24, the step in FIG. 14 described in the first embodiment is carried out to form insulating layers 21 and 22 all over the surface of the resulting structure. Moreover, as shown in FIG. 25, the step in FIG. 16 described in the first embodiment is carried out to remove a part of the insulating films 20 to 22. A silicide step is then carried out. Thereafter, an interlayer insulating film 23, required contact plugs and metal wiring layers, and the like are formed to obtain the structure shown in FIG. 20.

### <Effects>

As described above, the configuration described in the first embodiment is applicable not only to the memory cell array 2 but also to the MOS transistors in the peripheral circuit. The configuration according to the second embodiment thus exerts effects similar to those of the configuration according to the first embodiment.

As described above, the NAND flash memory according to the first and second embodiments of the present invention includes the select transistors ST1 and ST2 each having the first gate electrode GSG, the memory cell transistor MT having the second gate electrode GWL with the charge storage layer and the control gate, and the memory cell unit 5 having a plurality of the memory cell transistors MT connected together in series between the select transistors ST1 and ST2. The distance between the adjacent first gate electrodes GSG and the distance between the first gate electrodes GSG and the adjacent second gate electrode GWL are each at least double the distance between the adjacent second gate electrodes GWL. Moreover, the surface of the semiconductor substrate 10 between the adjacent second gate electrodes GWL is flush with the surface of the semiconductor substrate 10 between the first gate electrode GSG and the adjacent second gate electrode GWL. Furthermore, the surface of the semiconductor substrate 10 between the adjacent first gate electrodes GSG is positioned lower than the surface of the semiconductor substrate 10 between the first gate electrode GSG and the adjacent second gate electrode GWL.

Moreover, the NAND flash memory according to the above-described embodiments further includes the insulating film 20 formed on the side walls of the first gate electrode GSG and the second gate electrode GWL, and the anti-oxidant film 22 formed between the first gate electrodes GSG and between the first gate electrode GSG and the adjacent second gate electrode GWL to enable infiltration of an oxidant to be prevented.

The lower end of the anti-oxidant film 22 between the first gate electrodes GSG is positioned lower than the lower end of the anti-oxidant film 22 between the first gate electrode GSG and the second gate electrode GWL. In this case, in the configuration shown in FIG. 3, the size of the resulting step is equal to the sum of the thickness of the insulating film 20 and the amount of gouging d1. Furthermore, in the configuration shown in FIG. 19, the size of the resulting step is equal to the sum of the thickness of the insulating film 20, the thickness of the gate insulating film 13, and the amount of gouging d1.

Moreover, the surfaces of the control gate and the first gate electrode GSG are at least partly silicidized (silicide layer 18). The silicidized region 18 of the first gate electrode GSG has a larger film thickness than the silicidized region of the control gate. The difference in film thickness between the first gate electrode GSG and the control gate is equal to, for example, the thickness of the insulating film 20. As a result, the operational characteristics of the MOS transistor LV-TR and HV-TR can be improved.

Moreover, in the configuration according to the above-described second embodiment, the NAND flash memory further includes the MOS transistors LV-TR and HV-TR having the third gate electrodes GLV and GHV, respectively. The surface of the source or drain 19 of each of the MOS transistors LV-TR and HV-TR is positioned lower than the surface of the semiconductor substrate 10 between the first gate electrode GSG and the adjacent second gate electrode GWL.

Furthermore, the lower end of the anti-oxidant film 22 on the source or drain 19 of each of the MOS transistors LV-TR and HV-TR is positioned lower than the lower end of the anti-oxidant film 22 between the first gate electrode GSG and the second gate electrode GWL.

Moreover, the surfaces of the third gate electrodes GLV and GHV are at least partly silicidized (silicide layer 18). The silicidized region 18 of each of the third gate electrodes GLV and GHV has a larger film thickness than the silicidized region of the control gate. The difference in film thickness between each of the third gate electrodes GLV and GHV and the control gate is equal to, for example, the thickness of the insulating film 20.

The embodiments of the present invention are not limited to those described above. The side wall of the stack gate is not necessarily perpendicular but may be oblique to the surface of the semiconductor substrate 10. In this case, the “distance between WL and WL”, the “distance between SG and WL”, and the “distance between SG and SG” vary depending on the height of the stack gate at which the distance is measured. That is, the distances measured at the lowest portion of the stack gate are shorter than those measured at the highest portion of the stack gate. In the above-described embodiments, the case in which the distances are measured at the lowest portion of the stack gate as shown in FIG. 3 has been described. However, the above-described “distance” values may be measured at any height of the stack gate. The height at which the distances are defined does not particularly matter.

Furthermore, in the configurations described in the first and second embodiments, the silicide layer 18 may be omitted. However, the silicide layer 18 is preferably provided because the silicide layer 18 can function as a stopper for RIE carried out to form contact holes in which the contact plugs CP3 and CP4 are subsequently formed, as described above.

Moreover, the inter-gate insulating film 13 may be TiO₂, HfO, Al₂O₃, HfAlO, HfSiO, a tantalum oxide film, strontium titanate, barium titanate, lead zirconate titanate, a silicon oxynitride film, a silicon nitride film, or a stack of any of these films.

Furthermore, in the above-described embodiments, the p-type silicon substrate is used as the semiconductor substrate 10 by way of example. However, instead of the p-type silicon substrate, an n-type silicon substrate or an SOI substrate may be used. Alternatively, any other single-crystal semiconductor substrate containing silicon, such as an SiGe mixed crystal or an SiGeC mixed crystal may be used. Moreover, TiSi, BiSi, CoSi, TaSi, WSi, MoSi, or the like may be used as a material for the silicide layer 18. Additionally, instead of the polycrystalline silicon layers 14, 16, and 17, amorphous silicon, amorphous SiGe, amorphous SiGeC, or a stack structure of these materials may be used.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
select transistors formed on a semiconductor substrate and including first gate electrodes;
memory cell transistors including second gate electrodes with a charge storage layer and a control gate; and
a plurality of a memory cell units including a plurality of the memory cell transistors connected together in series between the two select transistors,
a distance between the first gate electrodes in a one of the plurality of the memory cell units and the first gate electrodes in an other of the plurality of the memory cell units, and a distance between one of the first gate electrodes and one of the second gate electrodes adjacent to each other, being each at least double a distance between the adjacent second gate electrodes,
a surface of the semiconductor substrate between the adjacent second gate electrodes being flush with the surface of the semiconductor substrate between one of the first gate electrodes and one of the second gate electrodes adjacent to each other, and
the surface of the semiconductor substrate between the first gate electrodes in the one of the plurality of the memory cell units and the first gate electrodes in the other of the plurality of the memory cell units being positioned lower than the surface of the semiconductor substrate between one of the first gate electrodes which is adjacent to the second gate electrodes and an adjacent one of the second gate electrodes.

2. The device according to claim 1, further comprising:
an insulating film formed on side walls of the first gate electrodes and the second gate electrodes; and
an anti-oxidant film formed between the first gate electrodes in the one of the plurality of the memory cell units and the first gate electrodes in the other of the plurality of the memory cell units, and between the first gate electrodes which is adjacent to the second gate electrodes and the adjacent one of the second gate electrodes to enable infiltration of an oxidant to be prevented, and
a lower end of the anti-oxidant film between first gate electrodes in the one of the plurality of the memory cell units and the first gate electrodes in the other of the plurality of the memory cell units is positioned lower than the lower end of the anti-oxidant film between the first gate electrodes which is adjacent to the second electrodes and the adjacent one of the second gate electrodes.

3. The device according to claim 1, further comprising:
a MOS transistor formed on the semiconductor substrate and including a third gate electrode,
wherein a surface of a source or drain of the MOS transistor is positioned lower than the surface of the semiconductor substrate between the first gate electrode which is adjacent to second gate electrodes and the adjacent one of the second gate electrodes.

4. The device according to claim 1,
wherein surfaces of the control gate and the first gate electrodes are at least partly silicidized, and
a silicidized region of the first gate electrodes has a larger film thickness than a silicidized region of the control gate.

5. The device according to claim 3,
wherein surfaces of the control gate and the third gate electrode are at least partly silicidized, and
a silicidized region of the third gate electrode has a larger film thickness than a silicidized region of the control gate.

6. The device according to claim 1,
wherein a gate length of the each of the second gate electrodes is less than a minimum processing size achieved by a photolithography technique.

7. A semiconductor memory device comprising:
select transistors including first gate electrodes formed on a semiconductor substrate with a first insulating film interposed therebetween and first impurity diffusion layers functioning as a source or a drain;
memory cell transistors including second gate electrodes having a charge storage layer and a control gate sequentially formed on the semiconductor substrate with a second insulating film interposed therebetween, and each of a second impurity diffusions layer functioning as a source or a drain, a distance between the adjacent first gate electrodes and a distance between one of the first gate electrodes and one of the second gate electrodes adjacent to each other being each at least double a distance between the adjacent second gate electrodes;
a plurality of a memory cell units in which the second impurity diffusion layers are connected together and which includes the select transistors formed so as to sandwich a plurality of the adjacent memory cell transistors; and
a third insulating film buried between a plurality of the adjacent second gate electrodes, between the first gate electrodes which is adjacent to the second gate electrodes and the adjacent one of the second gate electrodes, and between the first gate electrodes in a one of the plurality of the memory cell units and the first gate electrodes in an other of the plurality of the memory cell units, an interface between the third insulating film and a surface of the semiconductor substrate between the adjacent second gate electrodes being flush with an interface between the third insulating film and a surface of the semiconductor substrate between the first gate electrodes which is adjacent to the second gate electrodes and an adjacent one of the second gate electrodes, an interface between the third insulating film and a surface of the semiconductor substrate between the first gate electrodes in the one of the plurality of the memory cell units and the first gate electrodes in the other of the plurality of the memory cell units being at least partly positioned lower than the interface between the third insulating film and the surface of the semiconductor substrate between the first gate electrodes which is adjacent to the second gate electrodes and the adjacent one of the second gate electrodes.

8. The device according to claim 7, further comprising:
a fourth insulating film formed on side walls of the first gate electrodes and the second gate electrodes; and
an anti-oxidant film formed between the first gate electrodes in the one of the plurality of the memory cell units and the first gate electrodes in the other of the plurality of the memory cell units and between the first gate electrodes which is adjacent to the second gate electrodes and the adjacent one of the second gate electrodes to enable infiltration of an oxidant to be prevented,
wherein the third insulating film is located between the fourth insulating film and the anti-oxidant film,
a lower end of the anti-oxidant film between the first gate electrodes in the one of the plurality of the memory cell units and the first gate electrodes in the other of the plurality of the memory cell units is positioned lower than the lower end of the anti-oxidant film between the first gate electrodes which is adjacent to the second gate electrodes and the adjacent one of the second gate electrodes.

9. The device according to claim 7, further comprising:
a MOS transistor formed on the semiconductor substrate and including a third gate electrode,
wherein a surface of a source or drain of the MOS transistor is positioned lower than the interface between the third insulating film and the surface of the semiconductor substrate between one of the first gate electrodes which is adjacent to the second gate electrodes and the adjacent one of the second gate electrodes.

10. The device according to claim 7,
wherein surfaces of the control gate and the first gate electrode are at least partly silicidized, and
a silicidized region of the first gate electrodes has a larger film thickness than a silicidized region of the control gate.

11. The device according to claim 7,
wherein upper surfaces of the control gate and the first gate electrodes are silicidized, and
a silicidized region of the first gate electrodes includes a first portion where the silicidized region of the first gate electrodes is thicker than a silicidized region of the control gate in a direction perpendicular to the major surface of the semiconductor substrate, and a second portion where the silicidized region of the first gate electrodes is equal in thickness to the silicidized region of the control gate in the direction perpendicular to the major surface of the semiconductor substrate.

12. The device according to claim 10,
wherein surfaces of the control gate and the third gate electrode are at least partly silicidized, and
a silicidized region of the third gate electrode has a larger film thickness than a silicidized region of the control gate.

13. The device according to claim 7,
wherein a gate length of the each of the second gate electrodes is less than a minimum processing size achieved by a photolithography technique.

14. The device according to claim 7,
wherein the surfaces of the control gate and the first gate electrodes at least partly include a silicide layer formed by the silicidization,
the surface of the first gate electrodes has a recess in at least a part of the surface,
a position of bottom of the silicide layer in a region immediately below the recess is deeper than a bottom of the silicide layer in the control gate, and
a bottom of a plug contacts a surface of the recess.

15. A method for manufacturing a semiconductor memory device, the method comprising:
forming select transistors including first gate electrodes formed on a first region of a semiconductor substrate with a first insulating film interposed therebetween and first impurity diffusion layers functioning as a source or a drain;
forming a plurality of memory cell transistors including second gate electrodes having a charge storage layer and a control gate sequentially formed on a second region of the semiconductor substrate with a second insulating film interposed therebetween, and second impurity diffusion layers functioning as a source or a drain, any of the second impurity diffusion layers being connected to one of the first impurity diffusion layers, a distance between the adjacent first gate electrodes and a distance between the first gate electrodes which is adjacent to the second electrodes and the adjacent one of the second gate electrodes being each at least double a distance between the adjacent second gate electrodes;
forming a third insulating film so that the third insulating film covers the first gate electrodes, the second gate electrodes, and a surface of the semiconductor substrate; and
removing the third insulating film from the surface of the semiconductor substrate in a region between the adjacent first gate electrodes, with the third insulating film left on a surface of one of the first gate electrodes which is adjacent to the second gate electrodes and on a surface of the second gate electrodes.

16. The method according to claim 15,
wherein at least part of an other of the first impurity diffusion layers connected together on the surface of the semiconductor substrate is removed by removing of the third insulating film,
the method further comprising:
implanting ions again into the part where the other of the first impurity diffusion layers.

17. The method according to claim 15, further comprising:
forming a fourth insulating film on a side of the first gate electrodes and the second gate electrodes; and
forming an anti-oxidant film between the first gate electrodes and between one of the first gate electrodes which is adjacent to the second gate electrodes and the adjacent one of the second gate electrodes to enable infiltration of an oxidant to be prevented,
wherein a lower end of the anti-oxidant film between the first gate electrodes is positioned lower than the lower end of the antioxidant film between one of the first gate electrodes which is adjacent to the second gate electrodes and the adjacent one of the second gate electrodes.

18. The method according to claim 15, further comprising:
forming a MOS transistor including a third gate electrode, on the semiconductor substrate,
wherein a surface of a source or drain of the MOS transistor is positioned lower than a surface of the semiconductor substrate between one of the first gate electrodes which is adjacent to the second gate electrodes and the adjacent one of the second gate electrodes.

19. The method according to claim 17, further comprising:
etching parts of the third insulating film, the fourth insulating film and the anti-oxidant film after formation of the anti-oxidant film, in order to expose upper surfaces of the first gate electrodes and the second gate electrodes and to obtain a configuration wherein upper surfaces of the third insulating film, the fourth insulating film and the anti-oxidant film are lower in level between an adjacent the first gate electrodes than between an adjacent the first and second gate electrodes.

20. The method according to claim 15,
wherein the second gate electrodes are formed by a double patterning technique, and a gate length of the each of the second gate electrodes is less than a minimum processing size achieved by a photolithography technique.
